(19) United States
(12) Patent Application Publication
(10) Pub. No.: US 2013/0057319 A1
(43) Pub. Date: Mar. 7, 2013

(54) METHOD AND CIRCUIT FOR PRECISELY CONTROLLING AMPLITUDE OF CURRENT-MODE LOGIC OUTPUT DRIVER FOR HIGH-SPEED SERIAL INTERFACE

(71) Applicants: Xin Liu, El Dorado Hills, CA (US); Arvind Bomdica, Fremont, CA (US)

(72) Inventors: Xin Liu, El Dorado Hills, CA (US); Arvind Bomdica, Fremont, CA (US)

(21) Appl. No.: 13/226,371

(22) Filed: Sep. 6, 2011

(51) Int. Cl. H03K 3/00

(52) U.S. Cl. 327/108

(57) ABSTRACT

A method is provided for selecting a reference voltage value at a data transmission device that comprises a bias circuit and an output driver circuit. The method also includes providing a first electrical current at the bias circuit and a second electrical current at the output driver circuit. The second electrical current amplitude is approximately a multiple of the first electrical current amplitude, and the first electrical current is based on the reference voltage value. The method further includes driving a differential output the second electrical current. A circuit is also provided that includes a data output driver portion and a bias circuit portion. The bias circuit portion is a replica of the data output driver portion. The circuit is configured to drive a data signal. A computer readable storage device encoded with data for adapting a manufacturing facility to create an apparatus is also provided.

### BACKGROUND

1. Field of the Invention

Embodiments presented herein relate generally to electrical circuits and input/output (“I/O”) interfaces, and, more particularly, to a method and circuit for precisely controlling amplitudes of current-mode logic (“CML”) output drivers for serial interfaces.

2. Description of Related Art

Electrical circuits and data storage devices have evolved becoming faster and transmitting greater amounts of data. With the increased speed and bandwidth capabilities of electrical circuits and data storage devices, I/O interfaces must be adapted to be compatible with new system and technology requirements. As technologies for electrical circuits, communications and data storage devices have progressed, there has developed a greater need for reliability and stability, particularly in the area of I/O interfaces. However, voltage, current and signal speed considerations introduce substantial barriers to controlling output amplitude for I/O interfaces. Parameters such as output voltages for differential signals are particularly problematic.

Typically, in modern implementations for I/O interfaces, either current mirror or partial-replica bias circuits are used to control output amplitude of current-mode logic (“CML”) drivers. However, using either of these circuits to control output amplitude of I/O interfaces is inadequate to provide required performance and yield, especially at process, voltage and temperature (“PVT”) corners. That is, variations in I/O interfaces and CML circuits due to PVT corners cause low yield and inadequate performance using state of the art solutions. Current mirrors have inherent mismatches between bias current and CML driver current, and current mirrors inhibit the tuning of output voltages around a wide range of values. Partial replica bias circuits use a reference voltage to generate a bias circuit voltage for controlling driver current and voltage. However, inherent mismatches between bias current and CML driver current also exist in this solution and cause uncontrollable output signals in view of PVT corners and variations.

Embodiments presented herein eliminate or alleviate the problems inherent in the state of the art described above.

### SUMMARY OF EMBODIMENTS

In one aspect of the present invention, a method is provided. The method includes selecting a reference voltage value at a data transmission device, where the data transmission device comprises a bias circuit and an output driver circuit. The method also includes providing a first electrical current at the bias circuit and a second electrical current at the output driver circuit, wherein the amplitude of the second electrical current is approximately a multiple of the amplitude of the first electrical current, and wherein the first electrical current is based on the reference voltage value. The method further includes driving a differential signal pair output from the data transmission device using the second electrical current.

In another aspect of the invention, a circuit is provided. The circuit includes at least one data output driver portion and at least one bias circuit portion communicatively coupled to the at least one data output driver portion, wherein the at least one bias circuit portion is a replica of the at least one data output driver portion. The circuit is configured to drive a data signal.

In yet another aspect of the invention, a computer readable storage device encoded with data that, when implemented in a manufacturing facility, adapts the manufacturing facility to create an apparatus is provided. The apparatus is configured to drive a data signal. The circuit includes at least one data output driver portion and at least one bias circuit portion communicatively coupled to the at least one data output driver portion, wherein the at least one bias circuit portion is a replica of the at least one data output driver portion.

### BRIEF DESCRIPTION OF THE DRAWINGS

The embodiments herein may be understood by reference to the following description taken in conjunction with the accompanying drawings, in which the leftmost significant digit(s) in the reference numerals denote(s) the first figure in which the respective reference numerals appear, and in which:

FIG. 1 schematically illustrates a simplified block diagram of a computer system including one or more input/output (“I/O”) interfaces, according to one embodiment;

FIG. 2 shows a simplified block diagram of multiple computer systems connected via a network, according to one embodiment;

FIG. 3 provides a more detailed representation of one embodiment of a southbridge in the computer system provided in FIG. 1;

FIG. 4 illustrates an exemplary detailed representation of an I/O interface that is provided in FIGS. 1-3, according to one embodiment;

FIG. 5A illustrates a schematic diagram of an I/O interface, according to one exemplary embodiment;

FIG. 5B illustrates a schematic diagram of a portion of an I/O interface, according to one exemplary embodiment;

FIG. 6 illustrates a diagram of a differential signal, according to one exemplary embodiment;

FIG. 7 illustrates a schematic diagram of a portion of an implemented I/O interface, according to one exemplary embodiment;

FIG. 8 illustrates a schematic diagram of a portion of an I/O interface and an off-chip load, according to one exemplary embodiment;

FIG. 9A illustrates a flowchart depicting operation of a circuit for control and tuning of output voltages, according to one exemplary embodiment;

FIG. 9B illustrates a flowchart depicting a detailed representation of portions of FIG. 9A, according to one exemplary embodiment;

FIG. 9C illustrates a flowchart depicting a detailed representation of portions of FIG. 9A, according to one exemplary embodiment; and

FIG. 9D illustrates a flowchart depicting a detailed representation of portions of FIG. 9A, according to one exemplary embodiment.

While the embodiments herein are susceptible to various modifications and alternative forms, specific embodiments thereof have been shown by way of example in the drawings and are herein described in detail. It should be understood, however, that the description herein of specific embodiments is not intended to limit the invention to the particular forms disclosed, but, on the contrary, the intention is to cover all modifications, equivalents, and alternatives falling within the scope of the invention as defined by the appended claims.

### DETAILED DESCRIPTION

Illustrative embodiments of the instant application are described below. In the interest of clarity, not all features of an actual implementation are described in this specification. It will of course be appreciated that in the development of any such actual embodiment, numerous implementation-specific decisions may be made to achieve the developers' specific goals, such as compliance with system-related and business-related constraints, which may vary from one implementation to another. Moreover, it will be appreciated that such a development effort might be complex and time-consuming, but may nevertheless be a routine undertaking for those of ordinary skill in the art having the benefit of this disclosure.

Embodiments of the present application will now be described with reference to the attached figures. Various structures, connections, systems and devices are schematically depicted in the drawings for purposes of explanation only and so as to not obscure the disclosed subject matter with details that are well known to those skilled in the art. Nevertheless, the attached drawings are included to describe and explain illustrative examples of the present embodiments. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

As used herein, the suffixes “_b” and “_n” (or ‘“b” and “n”) denote a signal that is active-low (i.e., the signal is activated or enabled when a logical ‘0’ is applied to the signal). Signals not having these suffixes may be active-high (i.e., the signal is activated or enabled when a logical ‘1’ is applied to the signal). While various embodiments and Figures herein are described in terms active-high and active-low signals, it is noted that such descriptions are for illustrative purposes of various embodiments and that alternate configurations are contemplated in other embodiments not explicitly described in this disclosure.

For discussion purposes, it is assumed that a digital signal 0 may approximately equal 0V (i.e., GND 506/806) and a digital signal 1 may approximately equal the VDD 507. In alternate embodiments it is contemplated that values other than the GND 506/806 and the VDD 507 may be used for digital signals 0 and 1 respectively.

As used herein, the terms “substantially” and “approximately” may mean within 85%, 90%, 95%, 98% and/or 99%. In some cases, as would be understood by a person of ordinary skill in the art, the terms “substantially” and “approximately” may indicate that differences, while perceptible, may be negligent or be small enough to be ignored. Additionally, the term “approximately,” when used in the context of one value being approximately equal to another, may mean that the values are “about” equal to each other. For example, when measured, the values may be close enough to be determined as equal by one of ordinary skill in the art.

As used herein, the term “data transmission device” may be a current-mode output driver, a voltage- or current-mode pre-driver, an I/O interface, a central processing unit (“CPU”), a southbridge, a northbridge, a graphics processor unit (“GPU”), some combination thereof and/or the like, as would be understood by a person of ordinary skill in the art having the benefit of this disclosure.

As shown in the Figures and as described below, the circuits described herein may comprise various circuit components such as, but not limited to, metal oxide semiconductor field effect transistors (“MOSFETs”), resistors, capacitors, power node(s) and ground node(s). The MOSFETs may be n-type (nFET) or p-type (pFET), as would be known to a person of ordinary skill in the art. Similarly, the power nodes may be of an implementation specific and/or variable voltage level, as would be known to a person of ordinary skill in the art. In one or more embodiments, the nFETs and/or pFETs described herein may operate as switches. For example, the nFETs and/or pFETs may operate to complete circuit paths to allow the flow of current, and/or to drive signals.

Embodiments of the present application generally provide for precisely controlling amplitudes of CML output drivers for serial interfaces. It is contemplated that various embodiments described herein are not mutually exclusive. That is, the various embodiments described herein may be implemented simultaneously with, or independently of, each other, as would be apparent to one of ordinary skill in the art having the benefit of this disclosure. Various embodiments herein may be described in terms of serial advanced technology attachment (“SATA”) I/O interfaces. However, it should be noted that such descriptions are used in order to provide a basis for illustration and understanding of the embodiments presented herein. That is, the embodiments provided in this disclosure are not limited to SATA, but rather may be applied to other I/O interfaces as would be apparent to one of ordinary skill in the art having the benefit of this disclosure.

High speed I/O interfaces, such as SATA, require their associated interfaces to meet differential output signal parameters for different generations of the technologies (e.g., Gen1, Gen2, Gen3, etc.). In SATA, supply voltages may be as low as 1.0V, or lower. The generations of SATA must also meet strict differential peak-to-peak voltage parameters. For example, the differential peak-to-peak voltage may need to be as high as 1.0V. At submicron technologies requiring such parameters, variations (PVT corners) and/or the channel modulation effect can prevent operability and decrease yield. Therefore, it is difficult to tightly control currents and output voltages and simultaneously meet different parameter requirements.

Additional information on related I/O interfaces may be found in “Transmitter Equalization Method and Circuit Using Unit-Size and Fractional-Size Subdrivers in Output Driver for High-Speed Serial Interface,” by Xin Liu, et al., filed concurrently as a separate application and incorporated herein by reference in its entirety, and “Low-Power Wide-Tuning Range Common-Mode Driver for Serial Interface Transmitters,” by Xin Liu, et al., filed concurrently as a separate application and incorporated herein by reference in its entirety.

The embodiments described herein show a novel design that efficiently solves this problem. The embodiments described herein may show a CML driver circuit that uses a complete replica bias circuit and an output driver circuit. The embodiments described herein may allow for precise output voltage control while simultaneously meeting strict voltage requirements.

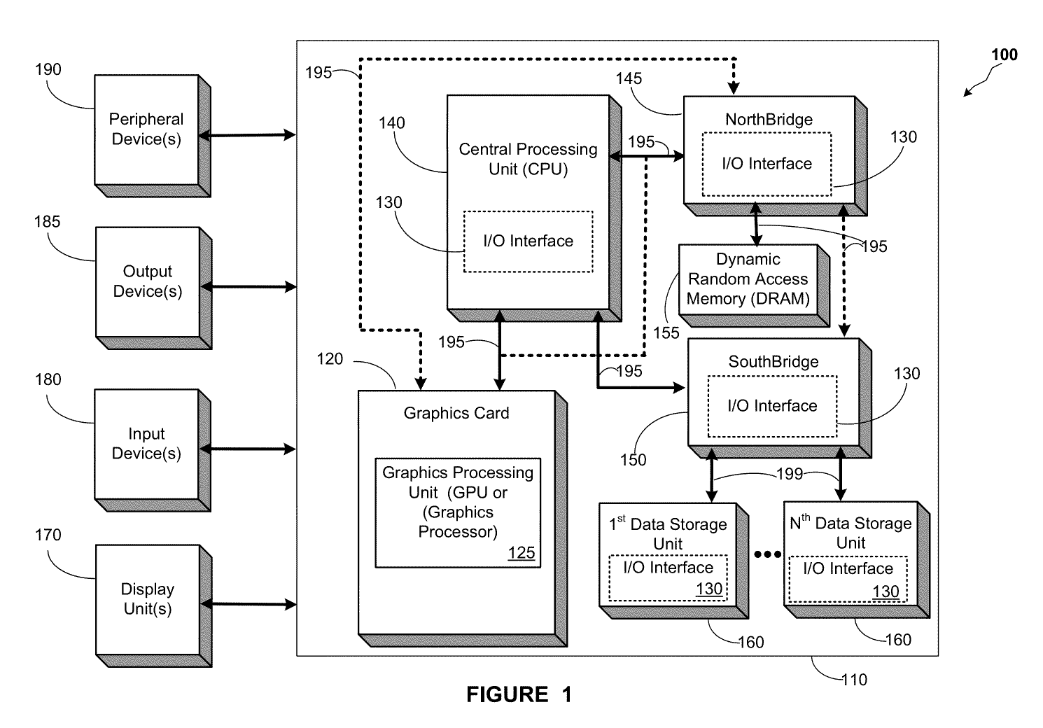

Turning now to FIG. 1, a block diagram of an exemplary computer system 100, in accordance with an embodiment of the present application, is illustrated. In various embodiments the computer system 100 may be a personal computer, a laptop computer, a handheld computer, a tablet computer, a mobile device, a telephone, a personal data assistant (“PDA”), a server, a mainframe, a work terminal, or the like. The computer system includes a main structure 110 which may be a computer motherboard, circuit board or printed circuit board, a desktop computer enclosure and/or tower, a laptop computer base, a server enclosure, part of a mobile device, personal data assistant (PDA), or the like. In one embodiment, the main structure 110 includes a graphics card 120. In one embodiment, the graphics card 120 may be a Radeon™ graphics card from Advanced Micro Devices (“AMD”) or any other graphics card using memory, in alternate embodiments. The graphics card 120 may, in different embodiments, be connected on a Peripheral Component Interconnect “(PCI”) Bus (not shown), PCI-Express Bus (not shown) an Accelerated Graphics Port (“AGP”) Bus (also not shown), or any other connection known in the art. It should be noted that embodiments of the present application are not limited by the connectivity of the graphics card 120 to the main computer structure 110. In one embodiment, computer runs an operating system such as Linux, Unix, Windows, Mac OS, or the like.

In one embodiment, the graphics card 120 may contain a graphics processing unit (GPU) 125 used in processing graphics data. The GPU 125, in one embodiment, may include one or more embedded memories (not shown). In one embodiment, the embedded memory(ies) may be an embedded random access memory (“RAM”), an embedded static random access memory (“SRAM”), or an embedded dynamic random access memory (“DRAM”). In one or more embodiments, the embedded memory(ies) may be an embedded RAM (e.g., an SRAM). In alternate embodiments, the embedded memory(ies) may be embedded in the graphics card 120 in addition to, or instead of, being embedded in the GPU 125. In various embodiments the graphics card 120 may be referred to as a circuit board or a printed circuit board or a daughter card or the like.

In one embodiment, the computer system 100 includes a central processing unit (“CPU”) 140, which is connected to a northbridge 145. The CPU 140 and northbridge 145 may be housed on the motherboard (not shown) or some other structure of the computer system 100. It is contemplated that in certain embodiments, the graphics card 120 may be coupled to the CPU 140 via the northbridge 145 or some other connection as is known in the art. For example, CPU 140, northbridge 145, GPU 125 may be included in a single package or as part of a single die or “chips” (not shown). Alternative embodiments which alter the arrangement of various components illustrated as forming part of main structure 110 are also contemplated. The CPU 140 and/or the northbridge 145, in certain embodiments, may each include one or more I/O interfaces 130. In certain embodiments, the northbridge 145 may be coupled to a system RAM (or DRAM) 155; in other embodiments, the system RAM 155 may be coupled directly to the CPU 140. The system RAM 155 may be of any RAM type known in the art; the type of RAM 155 does not limit the embodiments of the present application. In one embodiment, the northbridge 145 may be connected to a southbridge 150. In other embodiments, the northbridge 145 and southbridge 150 may be on the same chip in the computer system 100, or the northbridge 145 and southbridge 150 may be on different chips. In one embodiment, the southbridge 150 may have one or more I/O interfaces 130, in addition to any other I/O interfaces 130 elsewhere in the computer system 100. In various embodiments, the southbridge 150 may be connected to one or more data storage units 160 using a data connection or bus 199. The data storage units 160 may be hard drives, solid state drives, magnetic tape, or any other writable media used for storing data. In one embodiment, one or more of the data storage units may be SATA data storage units and the data connection 199 may be a SATA bus/connection. Additionally, the data storage units 160 may contain one or more I/O interfaces 130. In various embodiments, the central processing unit 140, northbridge 145, southbridge 150, graphics processing unit 125, DRAM 155 and/or embedded RAM may be a computer chip or a silicon-based computer chip, or may be part of a computer chip or a silicon-based computer chip. In one or more embodiments, the various components of the computer system 100 may be operatively, electrically and/or physically connected or linked with a bus 195 or more than one bus 195.

In different embodiments, the computer system 100 may be connected to one or more display units 170, input devices 180, output devices 185 and/or other peripheral devices 190. It is contemplated that in various embodiments, these elements may be internal or external to the computer system 100, and may be wired or wirelessly connected, without affecting the scope of the embodiments of the present application. The display units 170 may be internal or external monitors, television screens, handheld device displays, and the like. The input devices 180 may be any one of a keyboard, mouse, track-ball, stylus, mouse pad, mouse button, joystick, scanner or the like. The output devices 185 may be any one of a monitor, printer, plotter, copier or other output device. The peripheral devices 190 may be any other device which can be coupled to a computer: a CD/DVD drive capable of reading and/or writing to corresponding physical digital media, a universal serial buss (“USB”) device, Zip Drive, external floppy drive, external hard drive, phone and/or broadband modem, router/gateway, access point and/or the like. To the extent certain exemplary aspects of the computer system 100 are not described herein, such exemplary aspects may or may not be included in various embodiments without limiting the spirit and scope of the embodiments of the present application as would be understood by one of skill in the art.

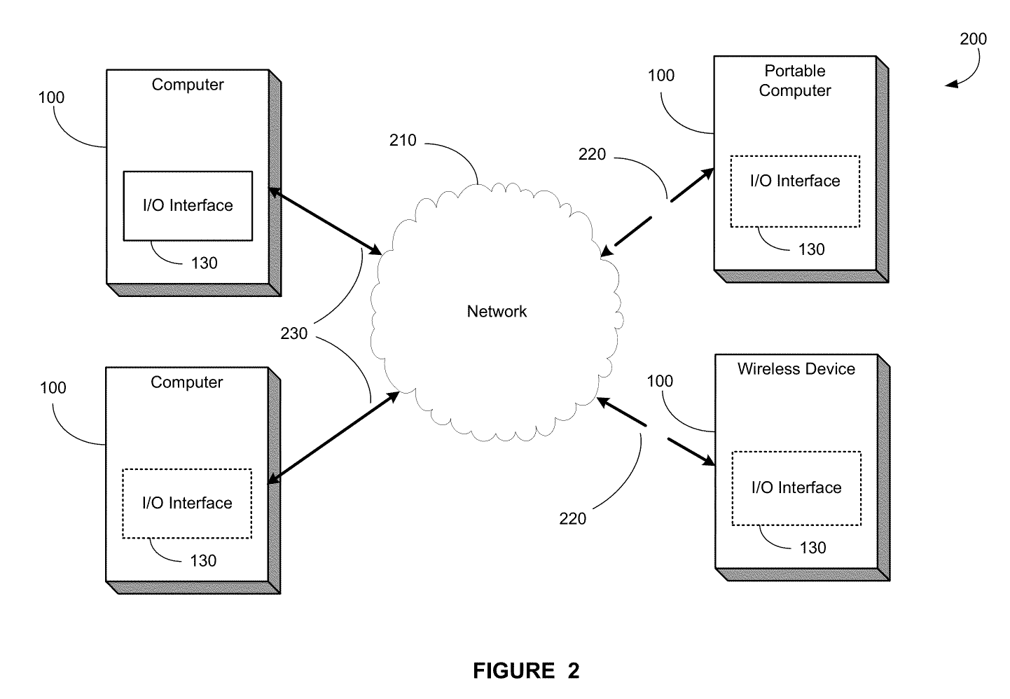

Turning now to FIG. 2, a block diagram of an exemplary computer network 200, in accordance with an embodiment of the present application, is illustrated. In one embodiment, any number of computer systems 100 may be communicatively coupled and/or connected to each other through a network infrastructure 210. In various embodiments, such connections may be wired 230 or wireless 220 without limiting the scope of the embodiments described herein. The network 200 may be a local area network (“LAN”), wide area network (“WAN”), personal network, company intranet or company network, the Internet, or the like. In one embodiment, the computer systems 100 connected to the network 200 via network infrastructure 210 may be a personal computer, a laptop computer, a handheld computer, a tablet computer, a mobile device, a telephone, a personal data assistant (“PDA”), a server, a mainframe, a work terminal, or the like. One or more computer systems 100 may, in various embodiments, contain one or more I/O interfaces 130. The number of computers depicted in FIG. 2 is exemplary in nature; in practice any number of computer systems 100 may be coupled/connected using the network 200.

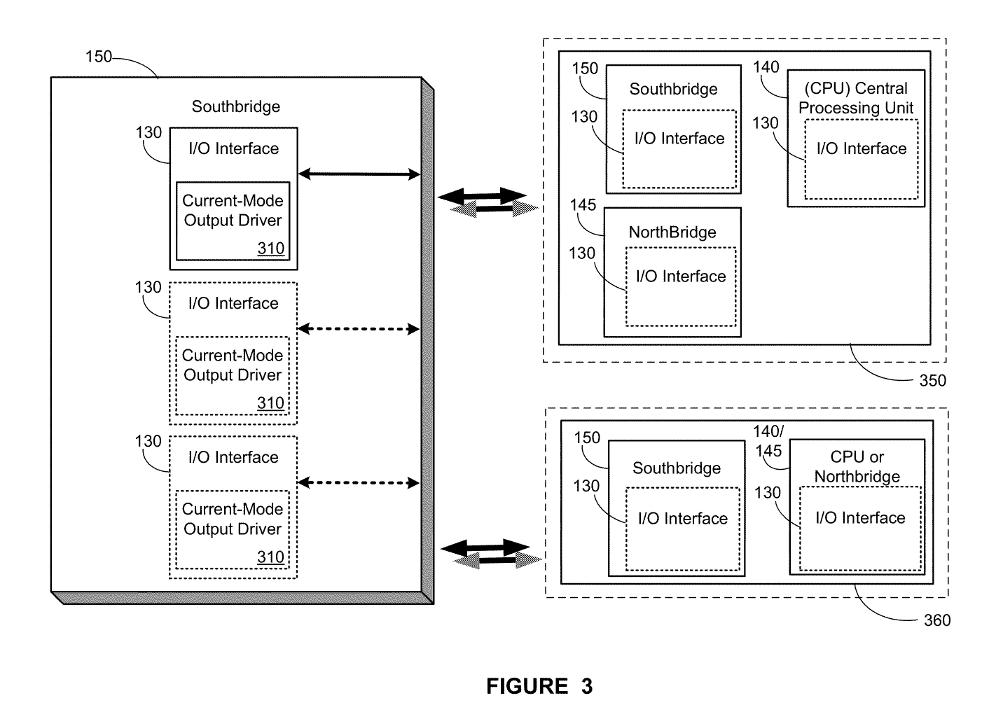

Turning now to FIG. 3, a block diagram of an exemplary southbridge 150, in accordance with an embodiment of the present application, is illustrated. In one embodiment, the southbridge 150 may contain one or more I/O interfaces 130 used in controlling data transmissions between the data storage units 160 and the rest of the computer system 100. The southbridge 150, in one embodiment as shown, may include an I/O interface(s) comprising a current-mode output driver 310. In one embodiment, the current-mode output driver 310 may contain control logic, described in further detail below. To the extent certain exemplary aspects of the southbridge 150 are not described herein, such exemplary aspects may or may not be included in various embodiments without limiting the spirit and scope of the embodiments of the present application as would be understood by one of skill in the art. For example, data storage units may be connected to various parts of the computer system 100 via external SATA (“eSATA”), USB, Firewire, advanced technology attachment (“ATA”), parallel ATA (“PATA”), integrated drive electronics (“IDE”), extended IDE (“EIDE”), connections and/or the like. Additionally, the southbridge 150 may contain I/O interfaces 130 adapted to perform I/O processes for different connection standards.

Referring still to FIG. 3, in one embodiment, the southbridge 150 and I/O interface(s) 130 may reside on the same silicon chip 350 as the CPU 140 and northbridge 145. In one alternate embodiment, the southbridge 150 and I/O interface(s) 130 may reside on the same silicon chip 360 as the CPU 140. In such embodiments, the silicon chip(s) 350/360 may be used in a computer system 100 in place of, or in addition to, the southbridge 150. The silicon chip(s) 350/360 may be housed on the motherboard (not shown) or other structure of the computer system 100.

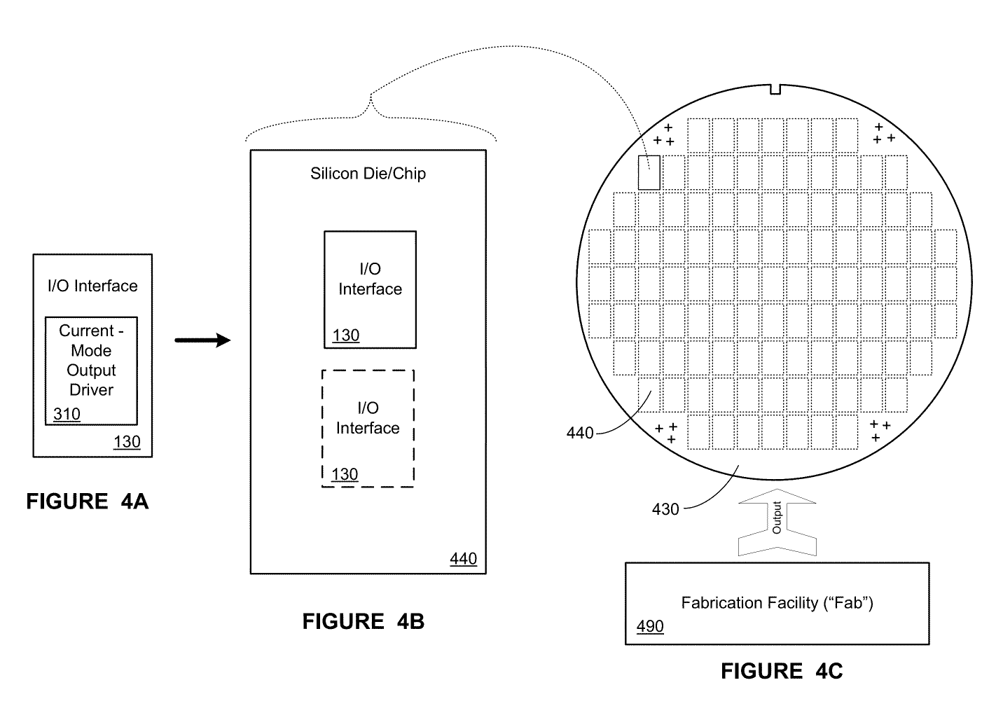

Turning now to FIG. 4A, a simplified, exemplary representation of the I/O interface 130, and, according to one or more embodiments, a current-mode output driver, which may be used in silicon die/chips 440, as well as devices depicted in FIGS. 1-3, according to various embodiments, is illustrated. However, those skilled in the art will appreciate that the I/O interface 130 may take on any of a variety of forms, including those previously described above, without departing from the scope of the instant application. The I/O interface 130 may be implemented as single elements (130) or in groups of logic (not shown).

Turning to FIG. 4B, the silicon die/chip 440 is illustrated as one or more the I/O interfaces 130, or any other configuration of the I/O interface as would be apparent to one of skill in the art having the benefit of this disclosure. As discussed above, various embodiments of the I/O interface 130 may be used in a wide variety of electronic devices, including, but not limited to, southbridge devices, central processing units, northbridge devices, motherboards, graphics cards, combinatorial logic implementations, stand-alone controllers, other integrated circuits (ICs), or the like.

Turning now to FIG. 4C, in accordance with one embodiment, and as described above, one or more of the I/O interfaces 130 may be included on the silicon die/chips 440 (or computer chip). The silicon die/chips 440 may contain one or more different configurations of the I/O interfaces 130 (e.g., I/O interfaces 130 configured to perform according to one or more connection standards, such as SATA). The silicon chips 440 may be produced on a silicon wafer 430 in a fabrication facility (or “fab”) 490. That is, the silicon wafers 430 and the silicon die/chips 440 may be referred to as the output, or product of, the fab 390. The silicon die/chips 440 may be used in electronic devices, such as those described above in this disclosure.

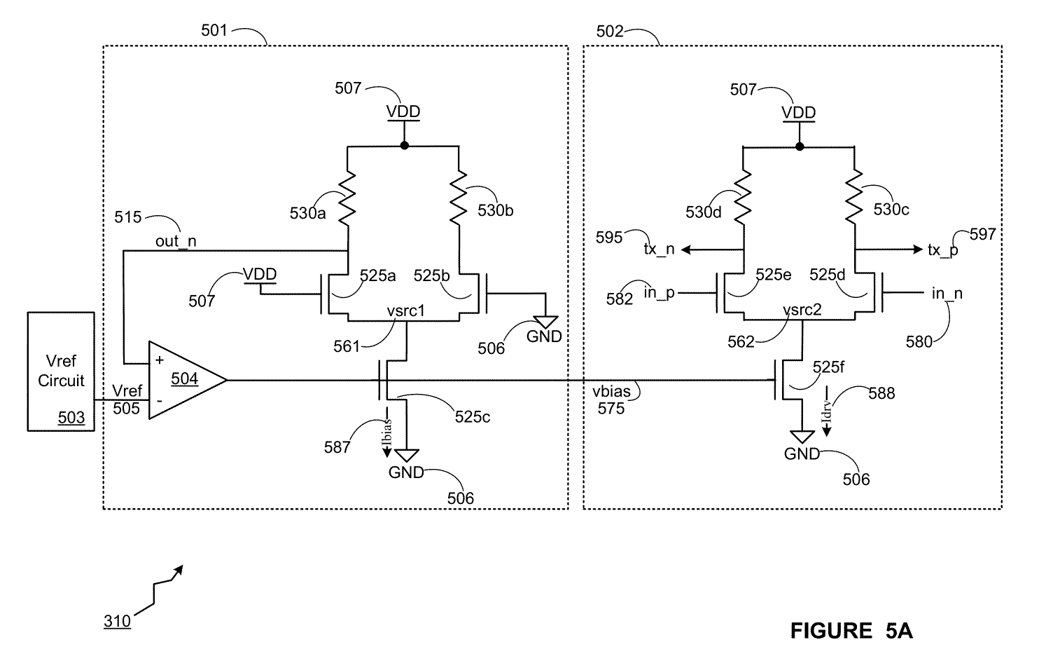

Turning now to FIG. 5A, a diagram of an exemplary implementation of a portion of the I/O interface 130 is illustrated, according to one embodiment. As previously described, in one or more embodiments, the I/O interface 130 may contain a current-mode output driver 310. As shown in FIG. 5A, the current-mode output driver 310 may be implemented in one or more portions (e.g., a voltage reference (vref) 503 portion, a bias circuit block 501 portion and/or an output driver block 502 portion that may function as a data output driver), or may be implemented as one logical block. It should be noted that in various embodiments shown in the Figures and described herein, the current-mode output driver 310 may be implemented in a vref 503 portion, a bias circuit block 501 portion and/or an output driver block 502 portion for purposes of illustration and conceptualization, however any configuration and/or partitioning of the current-mode output driver 310 may be used in accordance with the embodiments herein. The current-mode output driver 310 may also include a power voltage node VDD 507 (i.e., a supply voltage for supplying operating voltage to one or more circuits) and a ground voltage node GND 506.

The vref 503 portion, in one or more embodiments, may be adapted to generate a vref signal 505. The vref signal 505 may be generated using a voltage divider circuit (not shown) coupled to the power voltage node VDD 507 (i.e., a supply voltage for supplying operating voltage to one or more circuits) or using a bandgap voltage reference circuit (not shown). The vref signal 505 may be transmitted to a differential amplifier 504 in the bias circuit block 501. In one embodiment, the differential amplifier 504 may be a high gain differential amplifier. The differential amplifier 504 may have its negative input connected to the vref signal 505 and its positive input connected to a signal out_n 515 described below. The differential amplifier 504 may have its output connected to the gate of an nFET 525c in the bias circuit block 501 and to the gate of an nFET 525f in the output driver block 502. The output of the differential amplifier 504 may be referred to as a voltage bias (vbias) 575. In one embodiment, the bias circuit block 501 may also include an nFET 525a and an nFET 525b. The nFET 525a may have its gate connected to the VDD 507, and the nFET 525b may have its gate connected to the GND 506. The nFETs 525a-b may have their sources connected together and connected to the drain of the nFET 525c. The voltage at the sources of the nFETs 525a-b may be referred to as a first source voltage (vsrc1) 561. The nFET 525c may have its source connected to the GND 506. The nFET 525a may have its drain connected to a first connection of a resistor 530a, and the nFET 525b may have its drain connected to a resistor 530b. In one embodiment, the resistors 530a-b may be termination resistors. The node connection of the drain of nFET 525a and the first connection of the resistor 530a may be the out_n 515. As described above, the out_n 515 may be connected to the positive input of the operational amplifier 504. Such a connection (i.e., along with the negative input of the differential amplifier 504 being connected to vref 505) may provide a negative feedback loop such that the voltage of node out_n 515 is equal to the voltage vref 505 (i.e., Vout_n=vref 505 (Equation 1 below)). The second connections of the resistors 530a-b may be connected together and connected to the VDD 507. In one embodiment, applying a positive voltage via the vbias 575 at the gate of nFET 525c may cause a bias current Ibias 587 to flow from the VDD 507 through the resistor 530a and the nFETs 525a,c to the GND 506. Because the nFET 525b has its gate tied to the GND 506, no current will flow through the nFET 525b.

The nFET 525f of output driver block 502 may have its gate connected to vbias 575, in one embodiment. The nFET 525f may have its source connected to the GND 506. In one or more embodiments, the output driver block 502 may also include an nFET 525d and an nFET 525e. The nFETs 525d-e may have their sources connected together and connected to the drain of nFET 525f. The voltage at the sources of the nFETs 525d-e may be referred to as a second source voltage (vsrc2) 562. The gate of the nFET 525d may be connected to a differential input signal in_n 580, and the gate of the nFET 525e may be connected to a differential input signal in_p 582. In one embodiment, the differential input signals in_n 580 and in_p 582 form a differential signal pair. The drain of the nFET 525d may be connected to a first connection of a resistor 530c, and the drain of the nFET 525e may be connected to a first connection of a resistor 530d. In one embodiment, the resistors 530c-d may be termination resistors. The node connection of the drain of the nFET 525d and the first connection of the resistor 530c may be output as a differential signal tx_p 597, and the node connection of the drain of the nFET 525e and the first connection of the resistor 530d may be output as a differential signal tx_n 595. In one embodiment, the differential output signals tx_p 597 and tx_n 595 form a differential signal pair. The second connections of the resistors 530c-d may be connected together and connected to the VDD 507. In one embodiment, applying a positive voltage via the vbias 575 at the gate of nFET 525f (when the in_n 580 is “1”) may cause a drive current Idrv 588 to flow from the VDD 507 through the resistor 530c and the nFETs 525d,f to the GND 506 when the signal in_n 580 is a positive voltage. When the signal in_p 582 is a positive voltage (“1”), applying a positive voltage via the vbias 575 at the gate of nFET 525f may cause the drive current Idrv 588 to flow from the VDD 507 through the resistor 530d and the nFETs 525e,f to the GND 506.

As is depicted in FIG. 5A, in one or more embodiments, the structure of the bias circuit block 501 is a complete replica of (i.e., is the same as) the output driver block 502. The term replica may be used to denote matching structure, component types and/or operation between the circuits and blocks described herein. For example, the bias circuit block 501 and the output driver block 502 may be structured the same but have components with different attribute parameters. In such a case, the bias circuit block 501 would be a complete replica of the output driver block 502. In one embodiment, the resistors 530a-b may have the same resistance value, and the resistors 530c-d may have the same resistance value. The ratio of the resistance values of the resistors 530a-b to the resistance values of the resistors 530c-d may be described as a value “m”. That is, the resistance values of resistors 530c and 530d may be described as “Rtx” while the resistance values of resistors 530a and 530b (“Rbias”) may be described as “Rbias=m·Rtx” (i.e., “Rtx” multiplied by “m”) or “Rbias/Rtx=m”. Thus, the values of the resistors 530a and/or 530b may be integer multiples (or non-integer multiples) of resistance values of resistors 530c and/or 530d. For example, if Rtx is 50Ω (i.e., the resistance values of resistors 530c and/or 530d are 50Ω) and “m” is 3, the values of the resistors 530a and/or 530b may be 150Ω (that is, m·Rtx=3·50Ω=150Ω). The ratio of the current amplitude values of the currents Ibias 587 and Idrv 588 may be described as a value “n”. In one embodiment, the current Ibias 587 may be equal to the current Idrv 588 divided by “n” (i.e., “Ibias=Idrv/n” or “Idrv/Ibias=n”). That is, the amplitude value of the current Idrv 588 may be an integer multiple (or non-integer multiple) of the amplitude value of the current Ibias 587. For example, if the current Idrv 588 is 80 mA, and “n” is 4, that value of the amplitude of the current Ibias 587 may be 20 mA (that is, Idrv/n=80 mA/4=20 mA). In one embodiment, the relationship between the ratio value “m” and “n” can be described as:

m=¾·n (i.e., “m”=three fourths of “n”), or

m/n=¾.

In one embodiment, the size of the nFETs 525d-e in the output driver block 502 is “n” times the size of the nFETs 525a-b in the bias circuit block 501. In other words, for example, nFET 525d_{SIZE}=n·nFET 525a_{SIZE}. That is, the size of the nFETs 525d-e may be an integer multiple (or non-integer multiple) of the size of the nFETs 525a-b. Similarly, in one embodiment, the size of the nFET 525f in the output driver block 502 is “n” times the size of the nFET 525c in the bias circuit block 501. In other words, for example, nFET 525f_{SIZE}=n·nFET 525c_{SIZE}. That is, the size of the nFET 525f may be an integer multiple (or non-integer multiple) of the size of the nFET 525c.

The configurations generally described above with respect to FIG. 5A, may allow for the following relationships and equations:

Vout_{—}n=vref 505 (1) (as described above);

According to Ohm's Law, Vout_n is equal to VDD 507 minus the product of the resistance value of resistor 530a multiplied by the current Ibias 587, and therefore, Vout_n is equal to VDD 507 minus “m” multiplied by the resistance of resistor 530c (530d) multiplied by the current Ibias 587, thus Vout_n is equal to VDD 507 minus three fourths multiplied by “n” multiplied by the resistance of resistor 530c (530d) multiplied by the current Ibias 587, or:

$$\begin{matrix}Vout\_n = VDD - Ibias \cdot {R}_{530 a} \\ = VDD - Ibias \cdot m \cdot {R}_{530 c} \\ = VDD - 3 / 4 \cdot n \cdot Ibias \cdot {R}_{530 c} .\end{matrix} \qquad ( 2 )$$

It is noted that mismatches between the vsrc1 561 and the vsrc2 562 may cause the current Idrv 588 to be greater than or less than “n·Ibias” (“n” multiplied by Ibias). This may present a current discrepancy that may manifest itself as an inability to finely tune and/or control the output voltage of a serial communication interface. The channel modulation effect may compound this discrepancy between the currents as semiconductor technologies become smaller and smaller. The embodiments described with respect to FIG. 5A above (as well as those for the Figures below) eliminate (or at least alleviate) this issues. By providing the ability to finely tune and/or control the output voltages for serial communication interfaces, PVT corners may have less impact on circuit/product performance and/or yield.

Turning now to FIG. 5B, a diagram of an exemplary implementation of a portion of the I/O interface 130 is illustrated, according to one embodiment. As previously described, in one or more embodiments, the I/O interface 130 may contain a current-mode output driver 310. As shown in FIG. 5B, the current-mode output driver 310 may be implemented an alternate bias circuit block 501 portion. The alternate bias circuit block 599 portion depicted in FIG. 5B performs substantially similarly to the bias circuit block 501 portion depicted in FIG. 5A. As shown in FIG. 5B, the resistor 530b from FIG. 5A is removed to form the alternate bias circuit block 599. Because the gate of nFET 525b is connected to the GND 506 in both the bias circuit block 501 and the alternate bias circuit block 599, the nFETs 525b will remain “off” and will not allow any current to flow through the nFETs 525b in either the bias circuit block 501 or the alternate bias circuit block 599. As such, the drain of the nFET 525b (i.e., node out_p 566) in the alternate bias circuit block 599 may be connected to the VDD 507, the GND 506, or any other constant voltage in the system between the VDD 507 and the GND 506, or may be left floating. It should be noted that the alternate bias circuit block 599 depicted in FIG. 5B is also a complete replica bias circuit with respect to the output driver block 502, just as the bias circuit block 501 depicted in FIG. 5A, because flow of the current Ibias 587, as well as the operation of the circuit, remains the same in each implementation and mirrors the operation of the output driver block 502.

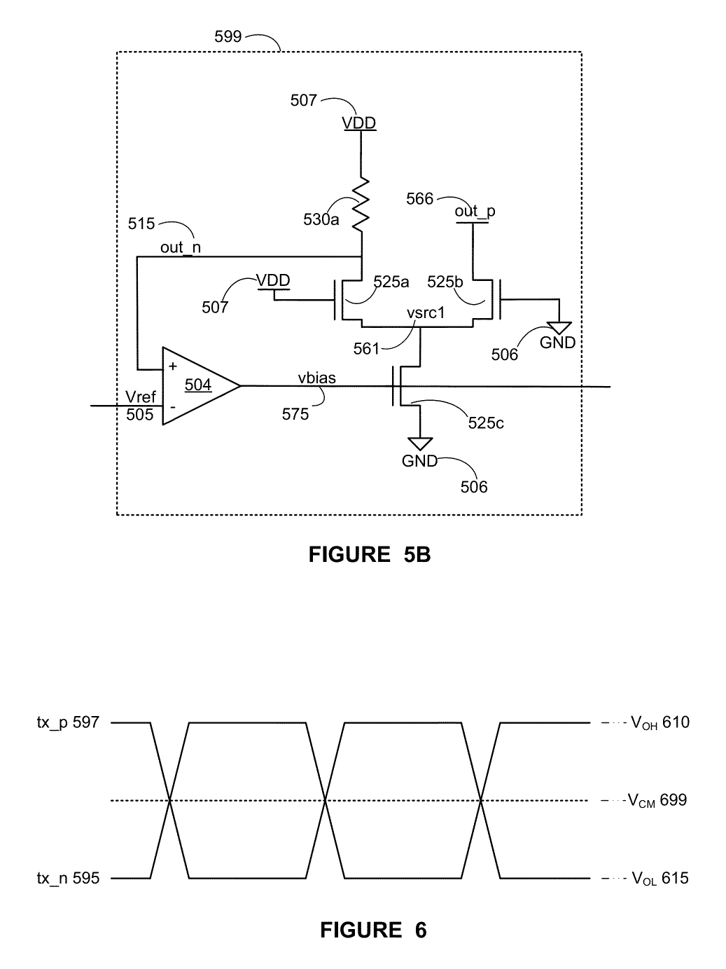

Turning now to FIG. 6, a schematic waveform diagram of a switching differential signal pair is depicted, in accordance with one embodiment. FIG. 6 shows two differential signals tx_p 597 and tx_n 595; the tx_p 597 and the tx_n 595 may be referred to as single-ended output signals, in one or more embodiments. In one embodiment, the values of the differential signals tx_p 597 and tx_n 595 may swing between a peak high single-ended output voltage V_{OH} 610 and a peak low single-ended output voltage V_{OL} 615. That is, tx_p 597 may have a high value of the V_{OH} 610 and a low value of V_{OL} 615. Similarly, tx_n 595 may have a high value of the V_{OH} 610 and a low value of the V_{OL} 615. The values of the differential signals tx_p 597 and tx_n 595 are equal to each other midway through the voltage swing at a common-mode voltage V_{CM} 699. The value of V_{CM} 699 may be described as V_{CM} 699=(tx_p 597+tx_n 595)/2, (i.e., the sum of the voltages of the tx_p 597 and the tx_n 595 divided by 2) or as V_{CM} 699=(V_{OH} 610+V_{OL} 615)/2, (i.e., the sum of the V_{OH} 610 and the V_{OL} 615, with the sum divided by 2). In one embodiment, the voltage vref 505 (described above with respect to FIG. 5A) may be set to a target value of V_{OL} 615. In one embodiment, the V_{CM} 699 may be determined as:

V_{CM}=VDD−⅔·(VDD−vref),

where VDD is the VDD 507 and vref is the vref 505.

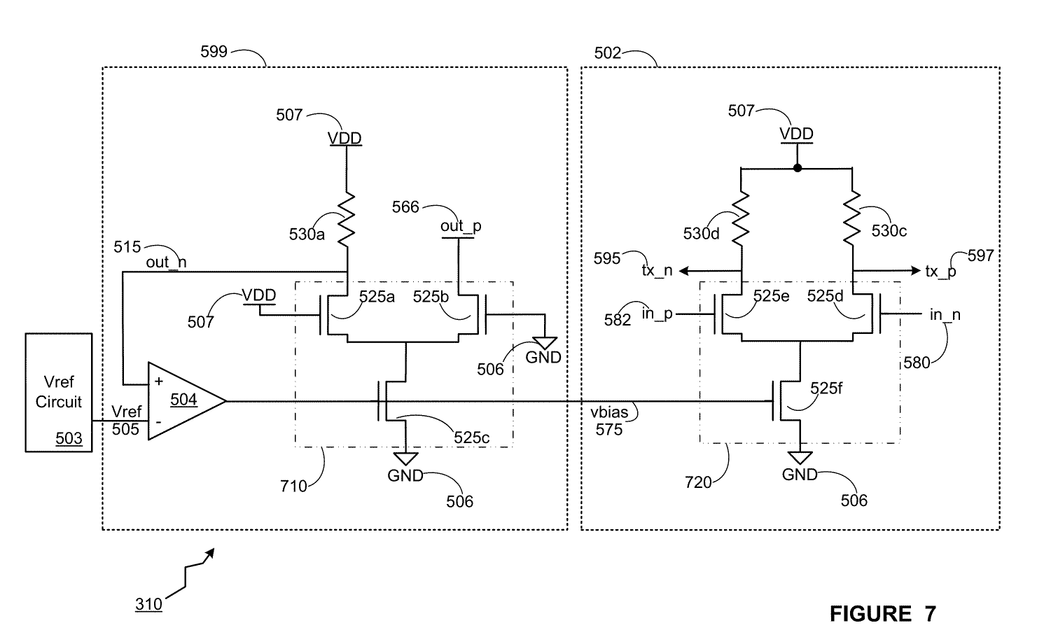

Turning now to FIG. 7, a diagram of an exemplary implementation of a portion of the I/O interface 130 is illustrated, according to one embodiment. As previously described, in one or more embodiments, the I/O interface 130 may contain a current-mode output driver 310. As shown in FIG. 7, the current-mode output driver 310 may be implemented in one or more portions (e.g., a voltage reference (vref) 503 portion, a bias circuit block 599 portion and/or an output driver block 502 portion that may function as a data output driver), or may be implemented as one logical block. It should be noted that in various embodiments shown in the Figures and described herein, the current-mode output driver 310 may be implemented in a vref 503 portion, a bias circuit block 599 portion and/or an output driver block 502 portion for purposes of illustration and conceptualization, however any configuration and/or partitioning of the current-mode output driver 310 may be used in accordance with the embodiments herein. The current-mode output driver 310 may also include a power voltage node VDD 507 (i.e., a supply voltage for supplying operating voltage to one or more circuits) and a ground voltage node GND 506.

FIG. 7 depicts an exemplary circuit representation, in accordance with one or more embodiments, of the current-mode output driver 310 as may be used and/or manufactured in an integrated circuit. The bias circuit block 599 is described above with respect to FIG. 5B, and the vref 503 and the output driver block 502 are described above with respect to FIG. 5A. In one or more embodiments, the bias circuit block 501 described above with respect to FIG. 5A may be used in place of the bias circuit block 599. The bias circuit block 599 may include a “drivelet” 710 that comprises nFETs 525a-c, and the output driver block 502 may include a “drivelet” 720 that comprises nFETs 525d-f. A “drivelet” may be a group of MOSFETs or switches that are configured to drive a current and/or supply a voltage to another circuit. In one embodiment, multiple instances (or slices) of the drivelets 710 and 720 may be used in parallel to provide an effective drive current or voltage. The multiple instances (slices) of the drivelets 710 and 720 may each connect to the resistors of the bias circuit block 599 and the output driver block 502 respectively. That is, multiple instances (or slices) of the drivelet 710 may connect to a single resistor 530a as shown in bias circuit block 599 (or to the single pair of resistors 503a-b, as shown in bias circuit block 501 in FIG. 5) and multiple instances (or slices) of the drivelet 720 may share the pair of resistors 530c-d as shown in output driver block 502. In other embodiments it is contemplated that each drivelet (slice) may have a corresponding resistor or pair of resistors having an effective resistance approximately equal to the single resistor or single pair of resistors as shown in bias circuit blocks 599 and 501 respectively, and having an effective resistance approximately equal to the single pair of resistors as shown in output driver block 502.

In one embodiment, the number of instances (slices) of the drivelets 710 and 720 in an implementation of the current-mode output driver 310 may be governed by the ratio: k=x·n, where “k” is the number of instances (slices) of the drivelet 720, where “x” is the number of instances (slices) of the drivelet 710, and where “n” is the ratio value between the current amplitudes for the currents Ibias 587 and Idrv 588, as described above. That is, the number of instances (slices) of the drivelet 720 may be an integer multiple (or non-integer multiple) of the number of instances (slices) of the drivelet 710. In various embodiments, the drivelets 710 and 720 may have multiple instances (slices) that produce effective currents Ibias 587 and Idrv 588 respectively. For example, an implementation using a value of 4 for “n” may have three (3) slices of drivelet 710 operating in parallel and twelve (12) slices of drivelet 720 operating in parallel. In such an implementation, each of the three slices of drivelet 710 operating in parallel may produce one third (⅓) of the effective current Ibias 587 of the bias circuit block 599 (or the bias circuit block 501), and each of the twelve slices of drivelet 720 operating in parallel may produce one twelfth ( 1/12) of the effective current Idrv 588 of the output driver block 502. In one or more embodiments, the slices 710 of the bias circuit blocks 599/501 may have shared nodes (e.g., the VDD 507 and the GND 506) as well as shared resistors (e.g., the resistors 530a and/or 530b). In one or more embodiments, one or more of the “k” slices 720 of the output driver block 502 may have shared nodes (e.g., the VDD 507 and the GND 506), shared bias circuits (e.g., bias circuit blocks 599/501 and/or one or more of the “x” bias circuit slices 710), as well as shared resistors (e.g., the resistors 530c and/or 530c).

In one embodiment, and as depicted in FIG. 7, the resistors 530c-d of the output driver block 502 may each be calibrated to about 50Ω, and the resistor 530a of the bias circuit block 599 may be calibrated to about “m”·50Ω. For example if “m” is three (3), the resistor 530a of the bias circuit block 599 may be calibrated to about 150Ω (and the resistors 530a-b of the bias circuit block 501 may each be calibrated to about 150Ω). It is noted that other embodiments described herein (e.g., such as those shown in FIGS. 5A, 5B, 6 and 8) the same or similar resistor calibrations may be used. It is also contemplated that in various embodiments, other resistance values for the resistors described herein may be used to conform to different industry standards or otherwise.

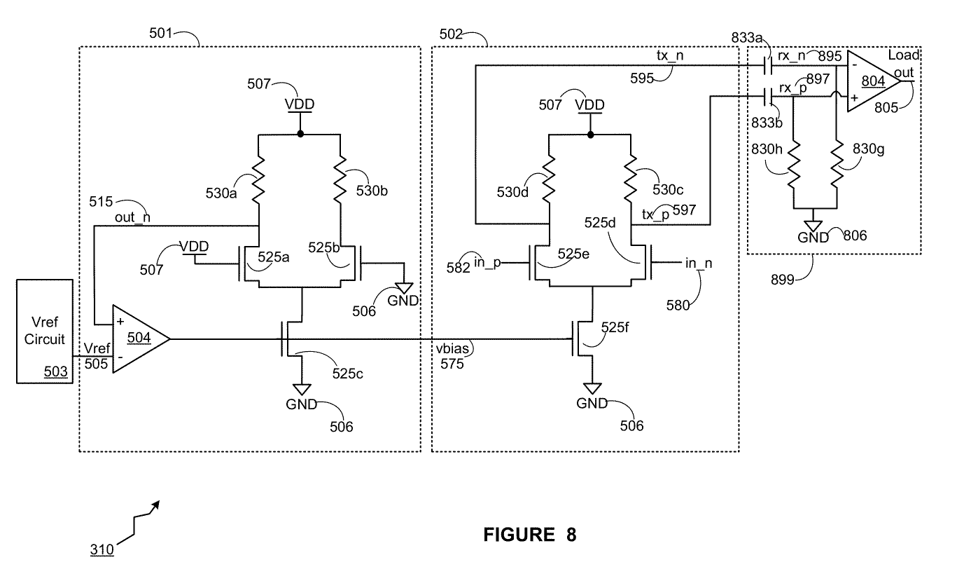

Turning now to FIG. 8, a diagram of an exemplary implementation of a portion of the I/O interface 130 is illustrated, according to one embodiment. As previously described, in one or more embodiments, the I/O interface 130 may contain a current-mode output driver 310. As shown in FIG. 8, the current-mode output driver 310 may be implemented in one or more portions (e.g., a voltage reference (vref) 503 portion, a bias circuit block 501 portion and/or an output driver block 502 portion that may function as a data output driver), or may be implemented as one logical block. In one embodiment, the bias circuit block 599 (as described above) may be used instead of the bias circuit block 501. It should be noted that in various embodiments shown in the Figures and described herein, the current-mode output driver 310 may be implemented in a vref 503 portion, a bias circuit block 501 portion and/or an output driver block 502 portion for purposes of illustration and conceptualization, however any configuration and/or partitioning of the current-mode output driver 310 may be used in accordance with the embodiments herein. The current-mode output driver 310 may also include a power voltage node VDD 507 (i.e., a supply voltage for supplying operating voltage to one or more circuits) and a ground voltage node GND 506.

As shown in FIG. 8, the I/O interface 130 may drive an off-chip load 899. The off-chip load 899 may be a circuit and/or device to which the I/O interface 130 and/or the current-mode output driver 310 drives a signal. The off-chip load 899 excluding the two decoupling capacitors 833a-b, in one embodiment, may act as a receiver. As exemplified in FIG. 8, the receiver may be schematically and/or conceptually simplified as two termination resistors 830g-h and a differential amplifier 804. In one embodiment, the resistors 830g-h may be calibrated to approximately 50Ω. The signal driven to the off-chip load 899 may be a differential signal, in one embodiment, or a signal operating in a different communications protocol in alternate embodiments. The off-chip load may comprise one or more capacitors 833a-b; in other embodiments, the capacitors 833a-b may be decoupling capacitors of the I/O interface 130 that effectively act as a load on the I/O interface 130. The capacitors 833a-b may be connected to the tx_n 595 and the tx_p 597 respectively. The capacitors 833a-b may also be connected to negative and positive inputs of a load differential amplifier 804 respectively. The negative input of the amplifier 804 may be a differential input rx_n to the off-chip load 899 that may correspond to the tx_n 595. The positive input of the amplifier 804 may be a differential input rx_p to the off-chip load 899 that may correspond to the tx_p 597. The load differential amplifier 804 may have an output load_out 805. The off-chip load 899 may also include resistors 830g-h. The resistor 830g may have one connection connected to the capacitor 833a and to the negative input of the load differential amplifier 804, and have its other connection connected to a ground voltage node GND 806. In one embodiment, the GND 806 may be the same ground voltage node as the GND 506, while in other embodiments the GND 806 may be a different ground voltage node. The resistor 830h may have one connection connected to the capacitor 833b and to the positive input of the load differential amplifier 804, and have its other connection connected to a ground voltage node GND 806.

In one embodiment, the signal driven to the off-chip load 899 may be a differential signal for transmitting data from the I/O interface 130, via the current-mode output driver 310, to the off-chip load 899. The following is an exemplary illustration of the operation of the circuit shown in FIG. 8.

Because the nFET 525b has its gate tied to the GND 506, the nFET 525b is “off”, while the nFET 525a has its gate tied to the VDD 507 and is “on”. The vbias 575 connected to the gate of the nFET 525c may activate the nFET 525c and turn it “on”. Thus, all the Ibias 587 current generated by the nFET 525c will flow down from the VDD 507 to the resistor 530a and the nFET 525a. Therefore, from Equation 2 above, the voltage at the out_n 515 (Vout_n) is equal to: VDD−¾·n·Ibias·R_{530c}. When the in_p 582 is logically high (e.g., the VDD 507), and the in_n 580 is logically low (e.g., the GND 506), the nFET 525e is “on” and the nFET 525d is “off”. The vbias 575 connected to the gate of the nFET 525f may activate the nFET 525f and turn it “on”. This means that the total tail current Idrv 588 generated by the nFET 525f will flow to the nFET 525e. Of that, three fourths (¾) of the Idrv 588 current will flow from the VDD 507 through the resistor 530d to the nFET 525e. The remaining Idrv 588 current (i.e., one fourth or ¼) will flow inside the output driver block 502 the nFET 525e the tx_n 595 from the capacitor 833a and the resistor 830g. The same amount of current (i.e., one fourth (¼) of the Idrv 588 current) will flow from the VDD 507 through the resistor 530c and outside via the tx_p to the capacitor 833b and the resistor 830h. Thus, it may be determined that the voltage at the tx_p 597 is:

Vₜₓ_{_{—}}ₚ=VDD−¼·Idrv·R_{530c,d}=VDD−¼·n·Ibias·R_{530c,d}=V_{OH} (3),

where VDD is the VDD 507, Idrv is the Idrv 588, R_{530c,d} is the resistance value of either of the resistors 530c or 530d, “n” is the ratio value between the Idrv 588 and the Ibias 587 as described above, Ibias is the Ibias 587, and V_{OH} is the high peak voltage V_{OH} 610 of the single-ended output as shown in FIG. 6. It may also be determined that the voltage at the tx_n 595 is:

Vₜₓ_{_{—}}ₙ=VDD−¾·Idrv·R_{530c,d}=VDD−¾·n·Ibias·R_{530c,d}=V_{OL} (4),

where VDD is the VDD 507, Idrv is the Idrv 588, R_{530c,d} is the resistance value of either of the resistors 530c or 530d, “n” is the ratio value between the Idrv 588 and the Ibias 587 as described above, Ibias is the Ibias 587, and V_{OL} is the low peak voltage V_{OL} 615 of the single-ended output as shown in FIG. 6. The differential output voltage is the difference (or absolute value of the difference) between the voltage Vₜₓ_{_{—}}ₚ and the voltage Vₜₓ_{_{—}}ₙ, which may be determined as:

|Vₜₓ_{_{—}}ₚ−Vₜₓ_{_{—}}ₙ|=V_{OH}−V_{OL}=0.5·Idrv·R_{530c,d}·0.5·n·Ibias·R_{530c,d} (5),

where Idrv is the Idrv 588 R_{530c,d} is the resistance value of either the resistor 530c or 530d, “n” is the ratio value between the Idrv 588 and the Ibias 587 as described above, Ibias is the Ibias 587, V_{OH} is the high peak voltage V_{OH} 610 of the single-ended output as shown in FIG. 6, and V_{OL} is the low peak voltage V_{OL} 615 of the single-ended output as shown in FIG. 6. From the above equations, it may be determined that:

Vₜₓ_{_{—}}ₙ=V_{OL}=Vout_{—}n=vref (6),

where Vₜₓ_{_{—}}ₙ is the voltage at the tx_n 595, V_{OL} is the low peak voltage V_{OL} 615 of the single-ended output as shown in FIG. 6, Vout_n is the voltage at the out_n 515, and vref is the vref 505. In one embodiment, the Vₜₓ_{_{—}}ₙ approximately equals the vref 505 and the out_n 515 while the circuit is under the off-chip load 899. Therefore, the voltage of the tx n595 (Vₜₓ_{_{—}}ₙ) in the output driver block 502 approximately (or exactly) matches the voltage at the out_n 515 (Vout_n) in the bias circuit block 501 (599). Because the nFET 525a and the nFET 525d are sized so that the drain-to-source voltage (Vds1) of the nFET 525a approximately equals the drain-to-source voltage (Vds4) of the nFET 525e, it may be determined that the voltage at the source of nFET 525a is approximately equal to the voltage at the source of the nFET 525e, or:

vsrc1=vsrc2 (7),

where vsrc1 is the vsrc1 561 and vsrc2 is the vsrc2 562. Thus, it may be verified that the voltage vsrc2 562 in the output driver block 502 approximately (or exactly) matches the voltage at the vsrc1 561 in the bias circuit block 501 (599). This voltage match allows for setting the vref 505 in order to determine the low peak voltage of the single-ended output as shown in FIG. 6 as a controllable, tunable, and or settable value.

Thus, from the above equations, it may be derived that the voltage at the tx_p 597 (Vₜₓ_{_{—}}ₚ) is:

Vₜₓ_{_{—}}ₚ=V_{OH}=VDD−⅓·(VDD−vref)=⅔·VDD+⅓·vref (8),

where V_{OH} is the high peak voltage V_{OH} 610 of the single-ended output as shown in FIG. 6, VDD is the VDD 507, and vref is the vref 505. It may also be derived from the above equations that the differential output voltage, i.e., the difference (or absolute value of the difference) between the voltage at the tx_p 597 (Vₜₓ_{_{—}}ₚ) and the voltage at the tx_n 595 (Vₜₓ_{_{—}}ₚ), is:

|V_{TX}_{_{—}}_{P}−V_{TX}_{_{—}}_{N}|=V_{OH}−V_{OL}=⅔·(VDD−Vref) (9),

where V_{OH} is the high peak voltage V_{OH} 610 of the single-ended output as shown in FIG. 6, V_{OL} is the low peak voltage V_{OL} 615 of the single-ended output as shown in FIG. 6, VDD is the VDD 507, and vref is the vref 505.

Therefore, for a known VDD (e.g., the VDD 507), a reference voltage (e.g., the vref 505) may be flexibly set to a desired value, and the single-ended output voltages (e.g., the V_{OH} 610 and the V_{OL} 615) and differential output voltage (e.g., |V_{TX}_{_{—}}_{P}−V_{TX}_{_{—}}_{N}|) may be achieved by the circuit(s) described in the exemplary embodiments shown herein according to equations (6), (8) and (9). In other words, the embodiments described herein provide for a unique circuit(s) and method(s) to for designing and operating a CML driver which may have its output amplitude precisely controlled and easily tuned.

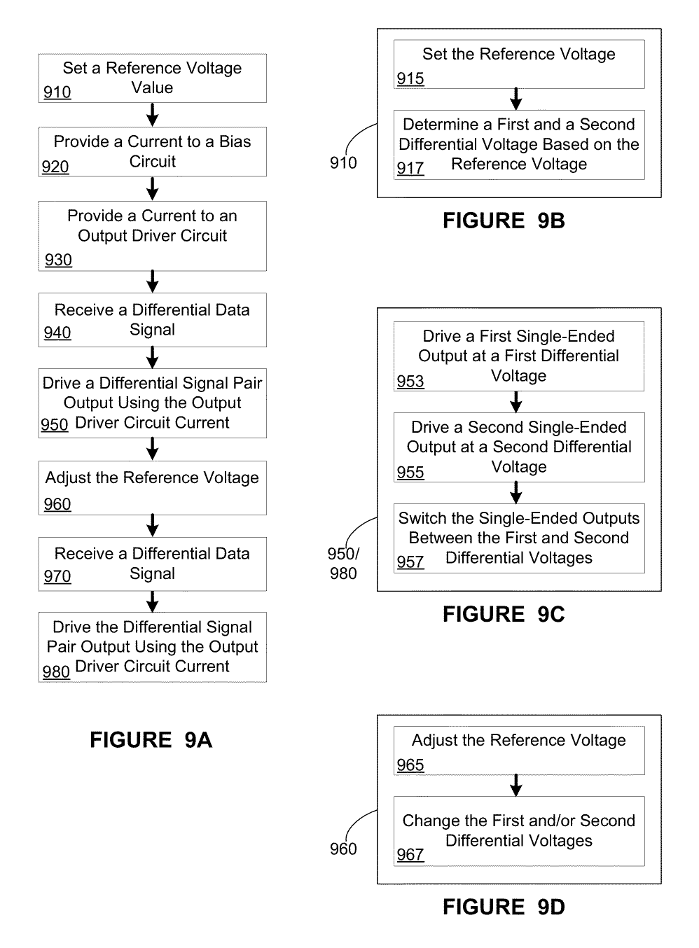

Turning now to FIG. 9A, a flowchart depicting operation of a circuit for control and tuning of output voltages is shown, in accordance with one or more embodiments. At 910, a reference voltage may be set to a desired value. In one embodiment, the reference voltage may be applied to a bias circuit. At 920 a first current is applied/provided to the bias circuit, and at 930, a second current is applied/provided to an output driver circuit. A differential data signal may be received at 940. In one embodiment, the differential data signal may be received at the output driver circuit. At 950, a differential data signal may be driven out on a differential pair output using the output driver circuit current. In one embodiment, the differential data signal that is driven out using the output driver circuit current may correspond to the received differential data signal from 940. At 960, the reference voltage may be adjusted/tuned. In one embodiment, the reference voltage may be adjusted/tuned in response to yield results, circuit performance and/or PVT corners. At 970, a differential data signal may be received. In one embodiment, the differential data signal may be received at the output driver circuit. At 980, a differential data signal may be driven out on a differential pair output using the output driver circuit current. In one embodiment, the differential data signal that is driven out using the output driver circuit current may correspond to the received differential data signal from 970.

Turning now to FIG. 9B, a flowchart depicting operation of a circuit for control and tuning of output voltages is shown, in accordance with one or more embodiments. FIG. 9B provides an exemplary detailed depiction of 910 from FIG. 9A. At 915, the reference voltage may be set by a designer, manufacturer or user, or the reference voltage may be automatically set. In one embodiment, the reference voltage may be applied to a bias circuit. At 917, a first and second differential voltage may be determined based on the reference voltage set in 915. In one embodiment, the first and second differential voltages may be a V_{OL} and a V_{OH}, as described herein. The V_{OL} and the V_{OH} may be determined at an output driver circuit. In one embodiment, the V_{OL} and the V_{OH} may be determined based on the structure of the output driver circuit.

Turning now to FIG. 9C, a flowchart depicting operation of a circuit for control and tuning of output voltages is shown, in accordance with one or more embodiments. FIG. 9C provides an exemplary detailed depiction of 950 and/or 980 from FIG. 9A. At 953, a first single-ended output signal may be driven out at a first differential output voltage. In one embodiment, the first differential voltage may be the V_{OL} or the V_{OH}, as described herein and above with respect to 917. At 955, a second single-ended output signal may be driven out at a second differential output voltage. In one embodiment, the second differential voltage may be the V_{OL} or the V_{OH}, as described herein and above with respect to 917. In one embodiment, if the first differential output voltage is the V_{OL}, the second differential voltage will be the V_{OH}. In another embodiment, if the first differential output voltage is the V_{OH}, the second differential voltage will be the V_{OL}. At 957, the single-ended output signals may be switched between the first and second differential voltages, for example, as shown in FIG. 6 and the accompanying description. It is noted that when one single-ended output signal is at a given differential voltage, the other single-ended output signal will be at the other differential voltage. During the switch between differential voltages, the single-ended output signal values will be equal at a V_{CM} voltage (as described above with respect to FIG. 6).

Turning now to FIG. 9D, a flowchart depicting operation of a circuit for control and tuning of output voltages is shown, in accordance with one or more embodiments. FIG. 9D provides an exemplary detailed depiction of 960 from FIG. 9A. At 965, the reference voltage may be adjusted/tuned by a designer, manufacturer or user, or the reference voltage may be automatically adjusted/tuned. In one embodiment, the reference voltage may be applied to a bias circuit in response to a low yield, circuit performance or PVT corners. At 967, the first and second differential voltage may be determined/changed based on the adjusted reference voltage in 965. In one embodiment, the first and second differential voltages may be a V_{OL} and a V_{OH}, as described herein. The V_{OL} and the V_{OH} may be determined/changed at an output driver circuit. In one embodiment, the V_{OL} and the V_{OH} may be determined/changed based on the structure of the output driver circuit in relation to the adjusted reference voltage.

It is contemplated that the steps as shown in FIGS. 9A-9D are not limited to the order in which they are described above. In accordance with one or more embodiments, the steps shown in FIGS. 9A-9D may be performed sequentially, in parallel, or in alternate order(s) without departing from the spirit and scope of the embodiments presented herein.

It is also contemplated that, in some embodiments, different kinds of hardware descriptive languages (HDL) may be used in the process of designing and manufacturing very large scale integration circuits (VLSI circuits) such as semiconductor products and devices and/or other types semiconductor devices. Some examples of HDL are VHDL and Verilog/Verilog-XL, but other HDL formats not listed may be used. In one embodiment, the HDL code (e.g., register transfer level (RTL) code/data) may be used to generate GDS data, GDSII data and the like. GDSII data, for example, is a descriptive file format and may be used in different embodiments to represent a three-dimensional model of a semiconductor product or device. Such models may be used by semiconductor manufacturing facilities to create semiconductor products and/or devices. The GDSII data may be stored as a database or other program storage structure. This data may also be stored on a computer readable storage device (e.g., data storage units 160, RAMs 155 (including embedded RAMs), compact discs, DVDs, solid state storage and/or the like). In one embodiment, the GDSII data (or other similar data) may be adapted to configure a manufacturing facility (e.g., through the use of mask works) to create devices capable of embodying various aspects described herein, in the instant application. In other words, in various embodiments, this GDSII data (or other similar data) may be programmed into a computer 100, processor 125/140 or controller, which may then control, in whole or part, the operation of a semiconductor manufacturing facility (or fab) to create semiconductor products and devices. For example, in one embodiment, silicon wafers containing I/O interfaces 130, current-mode logic drivers 310, bias circuit block(s) 501/599 and/or output driver circuit block(s) 502 may be created using the GDSII data (or other similar data).

It should also be noted that while various embodiments may be described in terms of SATA standards and serial I/O interfaces, it is contemplated that the embodiments described herein may have a wide range of applicability, not just for serial interfaces, as would be apparent to one of skill in the art having the benefit of this disclosure.

The particular embodiments disclosed above are illustrative only, as the embodiments herein may be modified and practiced in different but equivalent manners apparent to those skilled in the art having the benefit of the teachings herein. Furthermore, no limitations are intended to the details of construction or design as shown herein, other than as described in the claims below. It is therefore evident that the particular embodiments disclosed above may be altered or modified and all such variations are considered within the scope of the claimed invention.

Accordingly, the protection sought herein is as set forth in the claims below.

What is claimed:

1. A method, comprising:
selecting a reference voltage value at a data transmission device, where the data transmission device comprises a bias circuit and an output driver circuit;
providing a first electrical current at the bias circuit and a second electrical current at the output driver circuit, wherein the amplitude of the second electrical current is approximately a multiple of the amplitude of the first electrical current, and wherein the first electrical current is based on the reference voltage value; and
driving a differential signal pair output from the data transmission device using the second electrical current.

2. The method of claim 1, wherein the differential signal pair output comprises a first single-ended output signal and a second single-ended output signal, and further comprising:
driving the first single-ended output signal at a first differential voltage; and
driving the second single-ended output signal at a second differential voltage.

3. The method of claim 2, wherein driving the differential signal pair output comprises sending data using the differential signal pair output by switching the first and second single-ended output signals between the first and second differential voltages according to a differential signal operation.

4. The method of claim 2, wherein the first differential voltage value is approximately equal to the reference voltage value, and wherein the second differential voltage value is determined from the reference voltage value and a supply voltage value.

5. The method of claim 4, wherein the second differential voltage value is about equal to the sum of two thirds of the supply voltage value and one third of the reference voltage value.

6. The method of claim 4, further comprising:
changing the first differential voltage and the a second differential voltage by adjusting the reference voltage value; and
driving the first single-ended output signal and the second single-ended output signal at the changed first differential voltage and the second differential voltage respectively.

7. The method of claim 1, further comprising:
receiving a differential data signal at the data transmission device; and
wherein driving the differential signal pair output comprises sending the received differential data signal using the differential signal pair output by switching the first and second single-ended output signals between the first and second differential voltages according to a differential signal operation.

8. A circuit that comprises:
at least one data output driver portion;
at least one bias circuit portion communicatively coupled to the at least one data output driver portion, wherein the at least one bias circuit portion is a replica of the at least one data output driver portion; and
wherein the circuit is configured to drive a data signal.

9. The circuit of claim 8, that further comprises:
a reference voltage circuit communicatively coupled to the at least one bias circuit portion and adapted to provide an adjustable reference voltage to the at least one bias circuit portion;
an operating voltage node; and
a ground voltage node.

10. The circuit of claim 8, wherein the at least one data output driver portion comprises a first switch, a second switch, a third switch, a first resistor and a second resistor; and
wherein the at least one bias circuit portion comprises a fourth switch, a fifth switch, a sixth switch, a differential amplifier and at least one resistor.

11. The circuit of claim 10, wherein the at least one data output driver portion is configured to conduct a first electrical current and the at least one bias circuit portion is configured to conduct a second electrical current; and
wherein the amplitude of the second electrical current is approximately a first multiple of the amplitude of the first electrical current.

12. The circuit of claim 10, wherein the first switch and the second switch are of the same size, and wherein the fourth switch and the fifth switch are of the same size;
wherein the size of the first and second switches are approximately the first multiple of the size of the fourth and the fifth switches;
wherein the third switch has a size that is approximately the first multiple of the size of the sixth switch;
wherein the at least one resistor of the bias circuit portion has a resistance value that is approximately a second multiple of each of the resistance values of the first and second resistors of the data output driver portion; and
wherein the second multiple is three fourths of the first multiple.

13. The circuit of claim 10, wherein the at least one data output driver portion comprises a plurality of data output driver portions, and wherein the at least one bias circuit portion comprises a plurality of bias circuit portions;
wherein the plurality of data output driver portions comprises a number of data output driver portions that is approximately the first multiple of the number of bias circuit portions in the plurality of bias circuit portions;
wherein the total effective resistance of the plurality of first resistors in the plurality of data output driver portions is approximately fifty ohms and the total effective resistance of the plurality of second resistors in the plurality of data output driver portions is approximately fifty ohms;
wherein the total effective resistance of the plurality of at least one resistor in the plurality of bias circuit portions is approximately the second multiple of fifty ohms; and
wherein the second multiple is three fourths of the first multiple.

14. The circuit of claim 8, wherein the at least one data output driver portion is configured to conduct an electrical current wherein one quarter of the electrical current is driven as an output current.

15. A non-transitory, computer readable storage device encoded with data that, when implemented in a manufacturing facility, adapts the manufacturing facility to create an apparatus, wherein the apparatus comprises:
at least one data output driver portion;
at least one bias circuit portion communicatively coupled to the at least one data output driver portion, wherein the at least one bias circuit portion is a replica of the at least one data output driver portion; and
wherein the apparatus is configured to drive a data signal.

16. A non-transitory, computer readable storage device, as set forth in claim 15, encoded with data that, when implemented in a manufacturing facility, adapts the manufacturing facility to create an apparatus, wherein the apparatus further comprises:
a reference voltage circuit communicatively coupled to the at least one bias circuit portion and adapted to provide an adjustable reference voltage to the at least one bias circuit portion;
an operating voltage node; and
a ground voltage node.

17. A non-transitory, computer readable storage device, as set forth in claim 15, encoded with data that, when implemented in a manufacturing facility, adapts the manufacturing facility to create an apparatus, wherein the at least one data output driver portion comprises a first switch, a second switch, a third switch, a first resistor and a second resistor; and
wherein the at least one bias circuit portion comprises a fourth switch, a fifth switch, a sixth switch, a differential amplifier and at least one resistor.

18. A non-transitory, computer readable storage device, as set forth in claim 17, encoded with data that, when implemented in a manufacturing facility, adapts the manufacturing facility to create an apparatus, wherein the at least one data output driver portion is configured to conduct a first electrical current and the at least one bias circuit portion is configured to conduct a second electrical current; and
wherein the amplitude of the second electrical current is approximately a first multiple of the amplitude of the first electrical current.

19. A non-transitory, computer readable storage device, as set forth in claim 17, encoded with data that, when implemented in a manufacturing facility, adapts the manufacturing facility to create an apparatus, wherein the first switch and the second switch are of the same size, and wherein the fourth switch and the fifth switch are of the same size;
wherein the size of the first and second switches are approximately the first multiple of the size of the fourth and the switches;
wherein the third switch has a size that is approximately the first multiple of the size of the sixth switch;
wherein the at least one resistor of the bias circuit portion has a resistance value that is approximately a second multiple of each of the resistance values of the first and second resistors of the data output driver portion;
wherein the second multiple is three fourths of the first multiple;
wherein the at least one data output driver portion comprises a plurality of data output driver portions, and wherein the at least one bias circuit portion comprises a plurality of bias circuit portions;
wherein the plurality of data output driver portions comprises a number of data output driver portions that is approximately the first multiple of the number of bias circuit portions in the plurality of bias circuit portions;
wherein the total effective resistance of the plurality of first resistors in the plurality of data output driver portions is approximately fifty ohms and the total effective resistance of the plurality of second resistors in the plurality of data output driver portions is approximately fifty ohms;
wherein the total effective resistance of the plurality of at least one resistor in the plurality of bias circuit portions is approximately the second multiple of fifty ohms; and
wherein the second multiple is three fourths of the first multiple.

20. A non-transitory, computer readable storage device, as set forth in claim 15, encoded with data that, when implemented in a manufacturing facility, adapts the manufacturing facility to create an apparatus, wherein the at least one data output driver portion is configured to conduct an electrical current wherein one quarter of the electrical current is driven as an output current.
